(19) United States
(12) Patent Application Publication
(10) Pub. No.: US 2017/0023642 A1
(43) Pub. Date: Jan. 26, 2017

(54) LOST MOTION GASKET FOR SEMICONDUCTOR TEST, AND ASSOCIATED SYSTEMS AND METHODS

(71) Applicant: Translarity, Inc., Fremont, CA (US)

(72) Inventors: Douglas A. Preston, McMinnville, OR (US); Christopher T. Lane, Los Gatos, CA (US); Mark Gardiner, Portland, OR (US); Morgan T. Johnson, Beaverton, OR (US); Doug Buck, Salinas, CA (US); Nikolai Kalnin, Santa Clara, CA (US)

(73) Assignee: Translarity, Inc., Fremont, CA (US)

(21) Appl. No.: 15/166,716

(22) Filed: May 27, 2016

Related U.S. Application Data
(60) Provisional application No. 62/230,639, filed on Jun. 10, 2015.
(60) Provisional application No. 62/276,291, filed on Jan. 8, 2016.

(51) Int. Cl. G01R 31/28; G01R 1/04; G01R 1/073

(52) U.S. Cl. CPC G01R 31/2891; G01R 1/07378; G01R 1/0466; G01R 31/2889

(57) ABSTRACT

Systems and methods for testing semiconductor wafers using a wafer translator are disclosed herein. In one embodiment, an apparatus for testing semiconductor dies includes a semiconductor wafer translator having a wafer-side positioned to face toward a device under test, and an inquiry-side facing away from the wafer-side. The apparatus also includes a flexible arm peripherally connected to the wafer translator, and an evacuation opening within the flexible arm or within the wafer translator. The evacuation opening is open to a flow of a gas in a first position of the flexible arm, and closed to a flow of the gas in a second position of the flexible arm.

### CROSS-REFERENCES TO RELATED APPLICATIONS

This application claims the benefit of U.S. Provisional Application No. 62/230,639, filed Jun. 10, 2015, and U.S. Provisional Application No. 62/276,291, filed Jan. 8, 2016, both of which are hereby incorporated by reference in their entireties.

### FIELD OF THE INVENTION

The present invention relates generally to semiconductor test equipment, and more particularly relates to methods and apparatus for removably attaching a test interposer to a semiconductor wafer.

### BACKGROUND

Integrated circuits are used in a wide variety of products. Integrated circuits have continuously decreased in price and increased in performance, becoming ubiquitous in modern electronic devices. These improvements in the performance/cost ratio are based, at least in part, on miniaturization, which enables more semiconductor dies to be produced from a wafer with each new generation of the integrated circuit manufacturing technology. Furthermore, the total number of the signal and power/ground contacts on a semiconductor die generally increases with new, more complex die designs.

Prior to shipping a semiconductor die to a customer, the performance of the integrated circuits is tested, either on a statistical sample basis or by testing each die. An electrical test of the semiconductor die typically includes powering the die through the power/ground contacts, transmitting signals to the input contacts of the die, and measuring the resulting signals at the output contacts of the die. Therefore, during the electrical test at least some contacts on the die must be electrically contacted to connect the die to sources of power and test signals.

Conventional test contactors include an array of contact pins attached to a substrate, e.g., a relatively stiff printed circuit board (PCB). In operation, the test contactor is pressed against a wafer such that the array of contact pins makes electrical contact with the corresponding array of die contacts (e.g., pads or solderballs) on the dies of the wafer. Next, a wafer tester sends electrical test sequences (e.g., test vectors) through the test contactor to the input contacts of the dies of the wafer. In response to the test sequences, the integrated circuits of the tested die produce output signals that are routed through the test contactor back to the wafer tester for analysis and to determine whether a particular die passes the test.

In general, an increasing number of die contacts that are distributed over a decreasing area of the die results in smaller contacts spaced apart by smaller distances (e.g., a smaller pitch). Furthermore, a characteristic diameter of the contact pins of the test contactor generally scales with a characteristic dimension of the contact structures on the semiconductor die or the package. Therefore, as the contact structures on the die become smaller and/or have a smaller pitch, the contact pins of the test contactors become smaller, too. However, it is difficult to significantly reduce the diameter and pitch of the contact pins of the test contactor, e.g., because of the difficulties in machining and assembling such small parts, resulting in low yield and inconsistent performance from one test contactor to another. Furthermore, precise alignment between the test contactor and the wafer is difficult because of the relatively small size/pitch of the contact structures on the wafer. Accordingly, there remains a need for cost effective test contactors that can scale down in size with the size and pitch of the contact structure on the die.

### BRIEF DESCRIPTION OF THE DRAWINGS

The foregoing aspects and many of the attendant advantages of this invention will become more readily appreciated as the same become better understood by reference to the following detailed description, when taken in conjunction with the accompanying drawings, wherein:

FIG. 1A is an exploded view of a portion of a test stack for testing semiconductor wafers in accordance with an embodiment of the presently disclosed technology.

FIG. 1B is a partially schematic, top view of a wafer translator configured in accordance with an embodiment of the presently disclosed technology.

FIG. 1C is a partially schematic, bottom view of a wafer translator configured in accordance with an embodiment of the presently disclosed technology.

FIGS. 2A-2D are schematic, cross-sectional views of a wafer translator engaging with a wafer in accordance with an embodiment of the presently disclosed technology.

FIGS. 3A and 3B are schematic, cross-sectional views of a wafer translator engaging with a wafer in accordance with an embodiment of the presently disclosed technology.

FIG. 4 is a partially schematic, cross-sectional view of a wafer testing stack configured in accordance with an embodiment of the presently disclosed technology.

### DETAILED DESCRIPTION

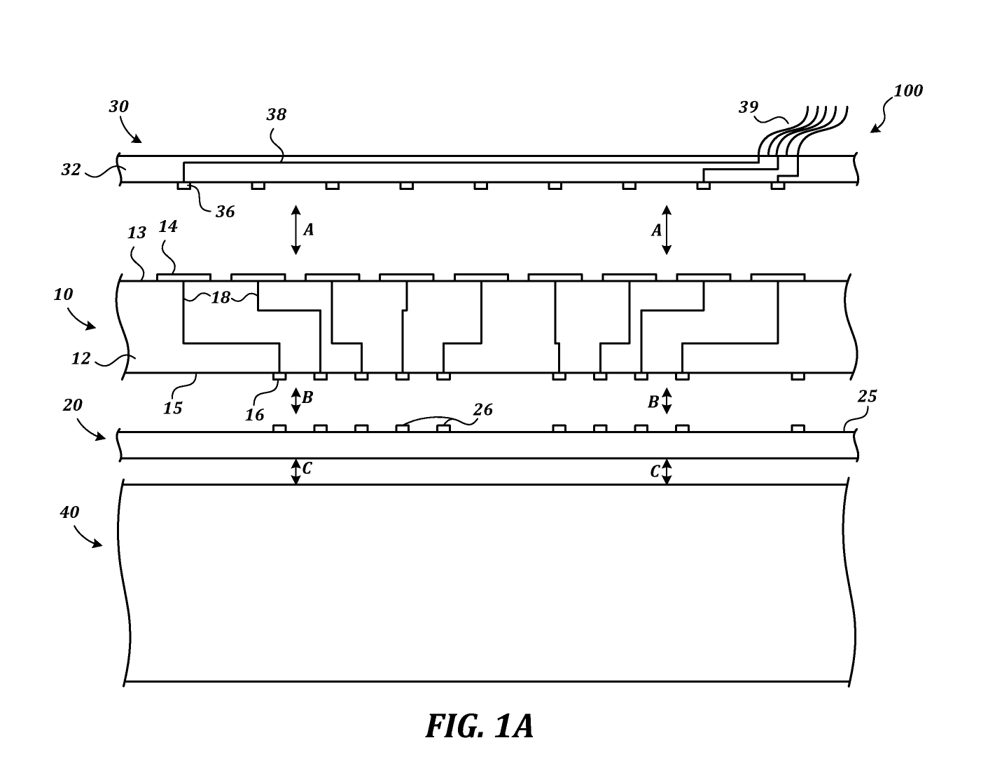

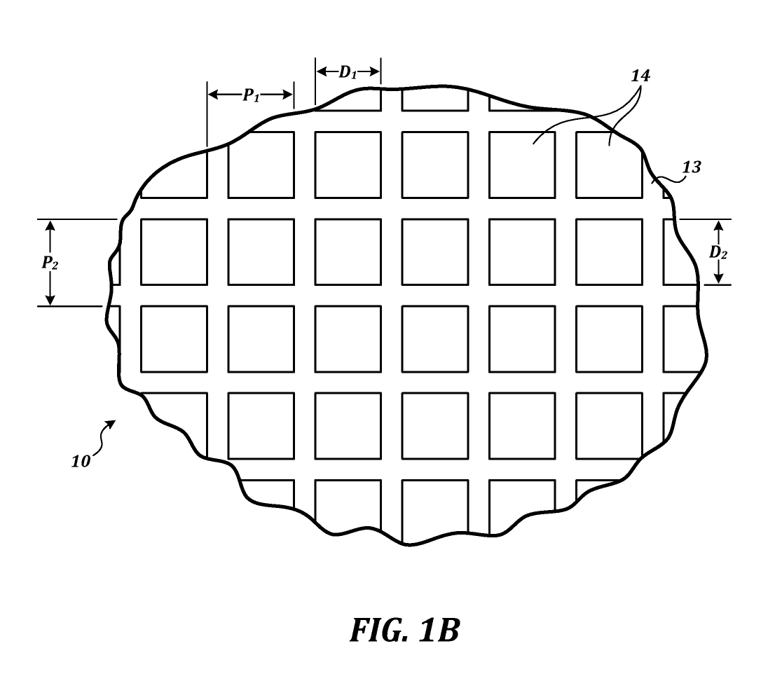

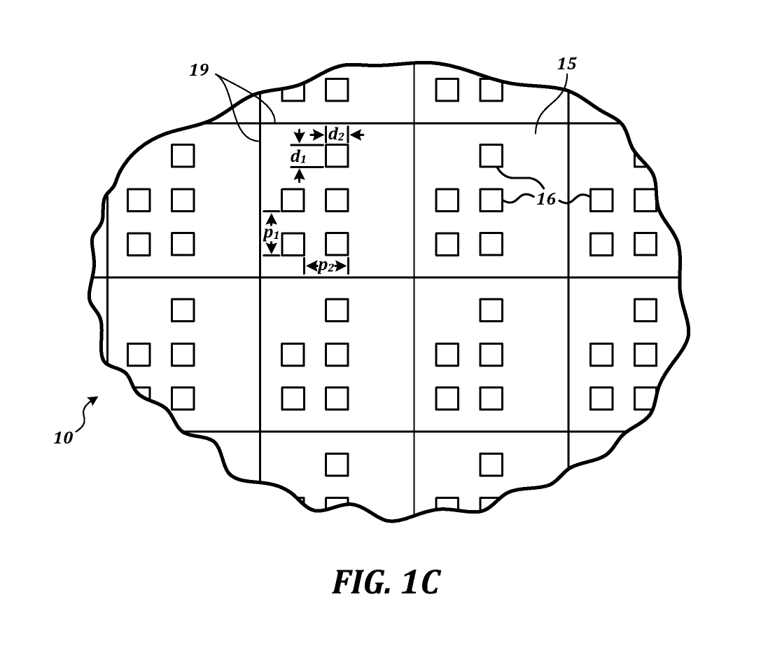

Specific details of several embodiments of representative wafer translators and associated methods for use and manufacture are described below. The wafer translators can be used for testing semiconductor dies on a wafer. The semiconductor dies may include, for example, memory devices, logic devices, light emitting diodes, micro-electro-mechanical-systems, and/or combinations of these devices. A person skilled in the relevant art will also understand that the technology may have additional embodiments, and that the technology may be practiced without several of the details of the embodiments described below with reference to FIGS. 1A-4.

Briefly described, methods and devices for testing dies on the semiconductor wafers are disclosed. The semiconductor wafers are produced in several diameters, e.g., 150 mm, 200 mm, 300 mm, 450 mm, etc. The disclosed methods and systems enable operators to test devices having pads, solderballs and/or other contact structures having small sizes and/or pitches. Solderballs, pads, and/or other suitable conductive elements on the dies are collectively referred to herein as “contact structures” or “contacts.” In many embodiments, the technology described in the context of one or more types of contact structures can also be applied to other contact structures.

In some embodiments, a wafer-side of the wafer translator carries the wafer-side contact structures having relatively small sizes and/or pitches (collectively, “scale”). The wafer-side contact structures of the wafer translator are electrically connected to corresponding inquiry-side contact structures having relatively larger sizes and/or pitches at the opposite, inquiry-side of the wafer translator. Therefore, once the wafer-side contact structures are properly aligned to contact the semiconductor wafers, the larger size/pitch of the opposing inquiry-side contact structures enable more robust contact (e.g., requiring less precision). The larger size/pitch of the inquiry-side contact structures may provide more reliable contact and be easier to align against the pins of the test contactor.

In at least some embodiments, contact between the wafer translator and the wafer is facilitated by a vacuum in a space between the wafer translator and the wafer. For example, a pressure differential between a lower pressure (e.g., sub-atmospheric pressure) in the space between the wafer translator and the wafer, and a higher outside pressure (e.g., atmospheric pressure) can generate a force over the inquiry-side of the wafer translator resulting in a sufficient electrical contact between the wafer-side contact structures and the corresponding die contacts of the wafer. A source of vacuum can be connected to the space between the wafer translator and the semiconductor wafer through one or more evacuation paths in the wafer chuck. In some embodiments, the vacuum is sealed by a vent seal in the evacuation opening (e.g., a hole) that is between the wafer translator and a peripherally attached flexible arm. In other embodiments, the vacuum is sealed by a gasket that is peripherally disposed about the wafer translator and an insert (e.g., an elastomer) between the gasket and the wafer chuck.

Many embodiments of the technology described below may take the form of computer- or controller-executable instructions, including routines executed by a programmable computer or controller. Those skilled in the relevant art will appreciate that the technology can be practiced on computer/controller systems other than those shown and described below. The technology can be embodied in a special-purpose computer, controller or data processor that is specifically programmed, configured or constructed to perform one or more of the computer-executable instructions described below. Accordingly, the terms “computer” and “controller” as generally used herein refer to any data processor and can include Internet appliances and hand-held devices (including palm-top computers, wearable computers, cellular or mobile phones, multi-processor systems, processor-based or programmable consumer electronics, network computers, mini computers and the like). Information handled by these computers can be presented at any suitable display medium, including a CRT display or LCD.

The technology can also be practiced in distributed environments, where tasks or modules are performed by remote processing devices that are linked through a communications network. In a distributed computing environment, program modules or subroutines may be located in local and remote memory storage devices. Aspects of the technology described below may be stored or distributed on computer-readable media, including magnetic or optically readable or removable computer disks, as well as distributed electronically over networks. Data structures and transmissions of data particular to aspects of the technology are also encompassed within the scope of the embodiments of the technology.

FIG. 1A is an exploded view of a portion of a test stack 100 for testing semiconductor wafers in accordance with an embodiment of the presently disclosed technology. The test stack 100 can route signals and power from a tester (not shown) to a wafer or other substrate carrying one or more devices under test (DUTs), and transfer the output signals from the DUTs (e.g., semiconductor dies) back to the tester for analysis and determination about an individual DUT's performance (e.g., whether the DUT is suitable for packaging and shipment to the customer). The DUT can be a single silicon die or multiple silicon dies (e.g., when using a parallel test approach). The signals and power from the tester may be routed through a test contactor 30 to a wafer translator 10, and further to the semiconductor dies on the wafer 20.

In some embodiments, the signals and power can be routed from the tester to the test contactor 30 using cables 39. Conductive traces 38 carried by a test contactor substrate 32 can electrically connect the cables 39 to contacts 36 on the opposite side of the test contactor substrate 32. In operation, the test contactor 30 can contact an inquiry-side 13 of a wafer translator 10 as indicated by arrows A. In at least some embodiments, relatively large inquiry-side contact structures 14 can improve aligning with the corresponding contacts 36 of the test contactor 30. The contact structures 14 at the inquiry-side 13 are electrically connected with relatively small wafer-side contact structures 16 on a wafer-side 15 of the translator 10 through conductive traces 18 of a wafer translator substrate 12. The size and/or pitch of the wafer-side contact structures 16 are suitable for contacting corresponding die contacts 26 of the wafer 20. Arrows B indicate a movement of the wafer translator 10 to make contact with an active side 25 of the wafer 20. As explained above, the signals and power from the tester can test the DUTs of the wafer 20, and the output signals from the tested DUTs can be routed back to the tester for analysis and a determination as to whether the DUTs are suitable for packaging and shipment to the customer.

The wafer 20 is supported by a wafer chuck 40. Arrows C indicate the direction of the wafer 20 mating with the wafer chuck 40. In operation, the wafer 20 can be held against the wafer chuck 40 using, e.g., vacuum V or mechanical clamping.

FIGS. 1B and 1C are partially schematic, top and bottom views, respectively, of a wafer translator configured in accordance with embodiments of the presently disclosed technology. FIG. 1B illustrates the inquiry-side 13 of the wafer translator 10. Distances between the adjacent inquiry-side contact structures 14 (e.g., pitch) are denoted P₁ in the horizontal direction and P₂ in the vertical direction. The illustrated inquiry-side contact structures 14 have a width D₁ and a height D₂. Depending upon the embodiment, the inquiry-side contact structures 14 may be squares, rectangles, circles or other shapes. Furthermore, the inquiry-side contact structures 14 can have a uniform pitch (e.g., P₁ and P₂ being equal across the translator 10) or a non-uniform pitch.

FIG. 1C illustrates the wafer-side 15 of the wafer translator 10. In some embodiments, the pitch between the adjacent wafer-side contact structures 16 can be p₁ in the horizontal direction and p₂ in the vertical direction. The width and height of the wafer-side contact structures 16 (“characteristic dimensions”) are denoted as d₁ and d₂. In some embodiments, the wafer-side contact structures 16 can be pins that touch corresponding die contacts on the wafer 30 (FIG. 1A). In general, the size/pitch of the inquiry-side contact structures 14 is larger than the size/pitch of the wafer-side contact structures 16, therefore improving alignment and contact between the test contactor and the wafer translator. The individual dies of the wafer 10 are typically separated from each other by wafer streets 19.

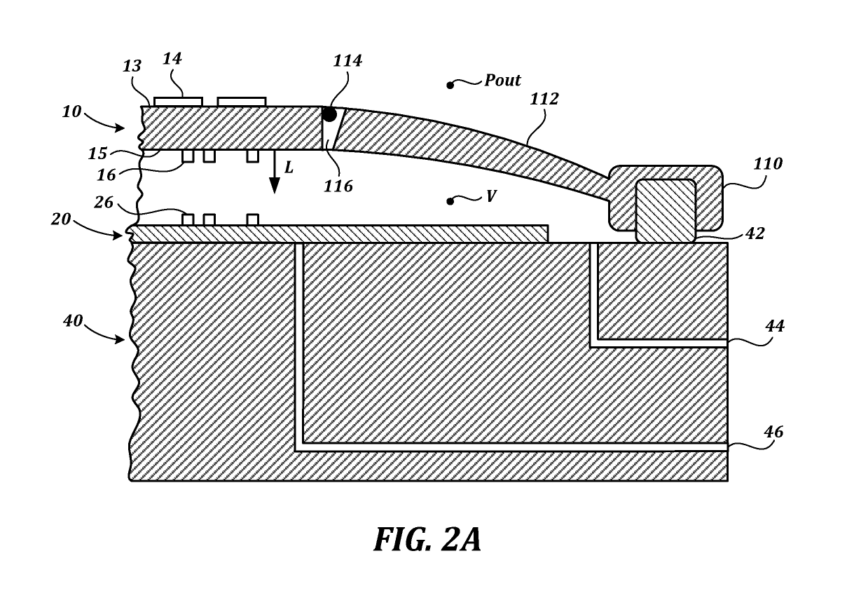

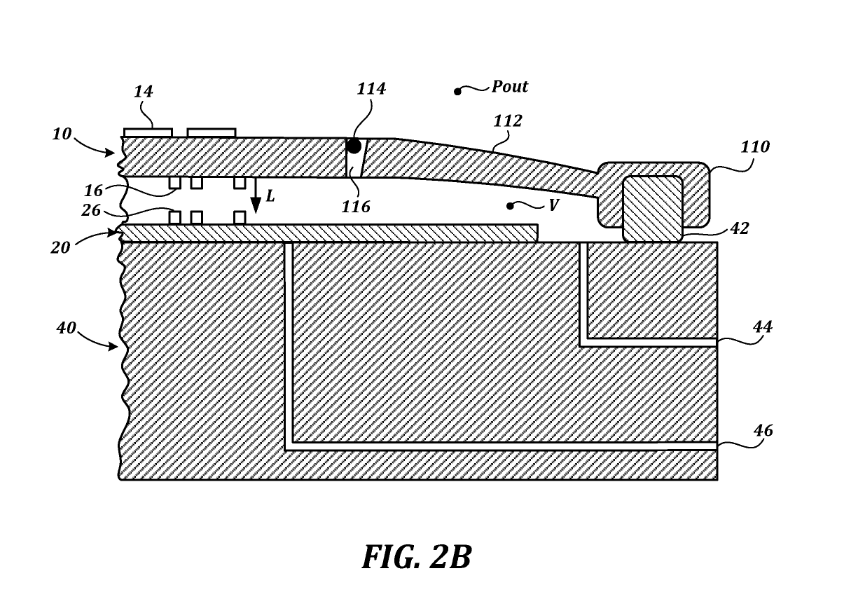

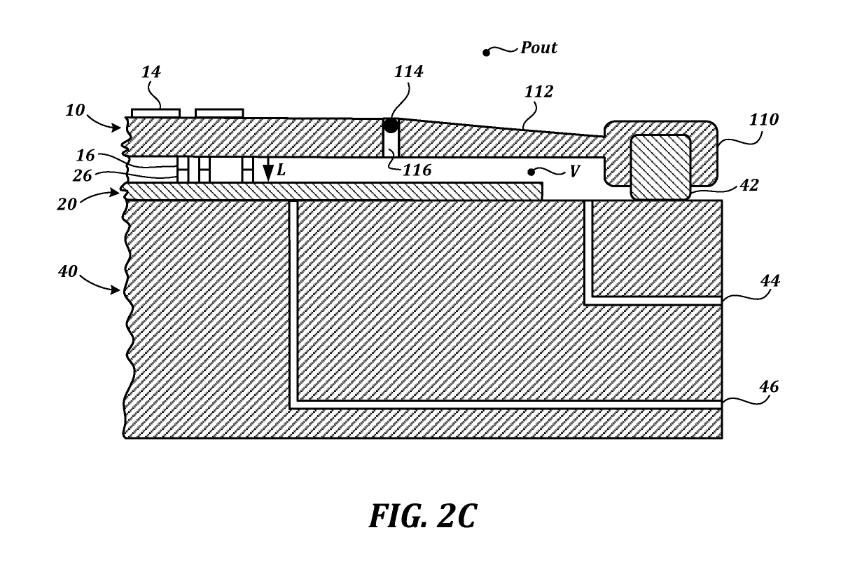

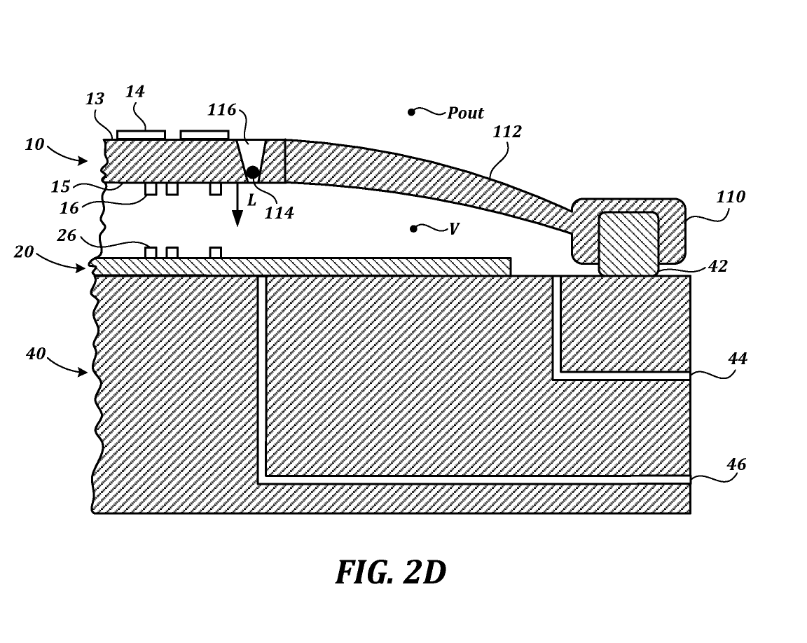

FIGS. 2A-2D are schematic, cross-sectional views of a wafer translator engaging with a wafer in accordance with an embodiment of the presently disclosed technology. As illustrated in FIGS. 2A-2D, a vacuum V can pull the wafer translator 10 closer toward, and into contact with, the wafer 20 as explained below.

In some embodiments, a flexible arm 112 connects the wafer translator 10 to a wafer translator attachment 110 that engages with a chuck attachment 42. In the illustrated embodiment, the flexible arm 112 is attached peripherally to a perimeter of the wafer translator 10. In other embodiments, the flexible arm 112 may partially or fully cover the wafer translator 10 while permitting access to the inquiry-side contact structures 14. For a generally circular wafer translator, the flexible arm 112 may also be generally circular. The flexible arm 112 can be made of an elastomer (e.g., rubber, silicon rubber, etc.), flexible substrate, or other materials. The illustrated wafer translator attachment 110 includes a groove that engages with a chuck attachment 42, but other engagement mechanisms are possible, for example, using fasteners, a vacuum, or an adhesive. In some embodiments, the wafer translator attachment 110 and the chuck attachment 42 are generally circularly disposed about the wafer translator 10. The chuck attachment 42 can be permanently or removably attached to the wafer chuck 40 using, e.g., fasteners or adhesives. In some embodiments, the wafer-side 15 of the wafer translator 10 faces the wafer 20 that is carried by the wafer chuck 40. The wafer 20 can be held in place, for example, by mechanical clamping or by applying a vacuum to an evacuation path 46. In some embodiments, an outside source of vacuum (not shown) can be connected to an evacuation path 44 to evacuate gas from and to reduce pressure (e.g., increase the vacuum V) in the space between the wafer translator 10 and the wafer 20.

In some embodiments, one or more evacuation openings 116 connect the space between the wafer translator 10 and the wafer 20 with a surrounding space that is at a pressure Pout (e.g., atmospheric pressure or above-atmospheric pressure). FIGS. 2A-2C illustrate the evacuation opening 116 between the flexible arm 112 and the wafer translator 10, and/or within the flexible arm 112. FIG. 2D illustrates the evacuation opening 116 inside the wafer translator 10. In some embodiments, the evacuation opening 116 that is inside the wafer translator 10 may face a partial die or an area without the die on the wafer 20 therefore preserving the testability of the dies on the wafer. The evacuation openings 116 may be circumferentially distributed about the wafer translator 10. The evacuation opening 116A may house a vent seal 114 (e.g., an elastomer).

In the embodiments illustrated in FIGS. 2A-2C, when the wafer translator 10 is away from the wafer 20, the vent seal 114 does not fully close the evacuation opening 116, therefore enabling a slower ramp up of the vacuum V in the space between the wafer translator 10 and the wafer 20. In response to increasing a pressure differential between the Pout and the vacuum V, the wafer translator 10 can move closer to the wafer 20 in a direction indicated by arrow L.

FIG. 2B illustrates the wafer translator 10 that is pulled closer toward the wafer 20 (in the direction of arrow L) by the vacuum V. As the wafer translator 10 moves toward the wafer 20, the space between the evacuation opening 116 and the vent seal 144 becomes smaller. In some other embodiments, the vent seal 144 may be generally flat to at least partially cover the opening of the evacuation opening 116 (e.g., the vent seal slides over the opening of the evacuation opening 116 as the wafer translator 10 is drawn closer to the wafer 20).

FIG. 2C illustrates the wafer translator 10 in contact with the wafer 20. The pressure differential between the pressure Pout and the vacuum V may maintain contact between the wafer translator 10 and the wafer 20. In some embodiments, the vent seal 114 blocks the evacuation opening 116 when the wafer translator 10 is in contact with the wafer 20, therefore helping to stabilize and maintain the vacuum V. In some embodiments, electrical testing of the wafer 20 commences after the wafer-side contact structure 16 contacts the corresponding die contacts 26.

In the embodiments illustrated in FIG. 2D, the evacuation opening 116 is in the wafer translator 10. In other embodiments, the evacuation opening 116 may be located partially in the wafer translator 10 and partially in the flexible arm 112. In response to increasing a pressure differential between the Pout and the vacuum V, the wafer translator 10 can move closer to the wafer 20 in the direction indicated by the arrow L.

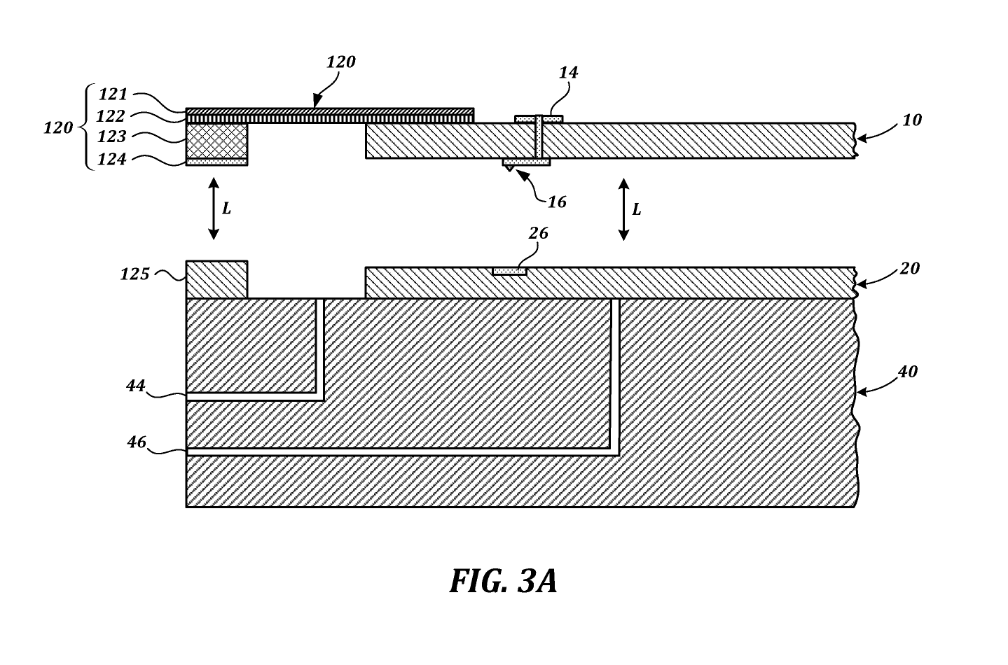

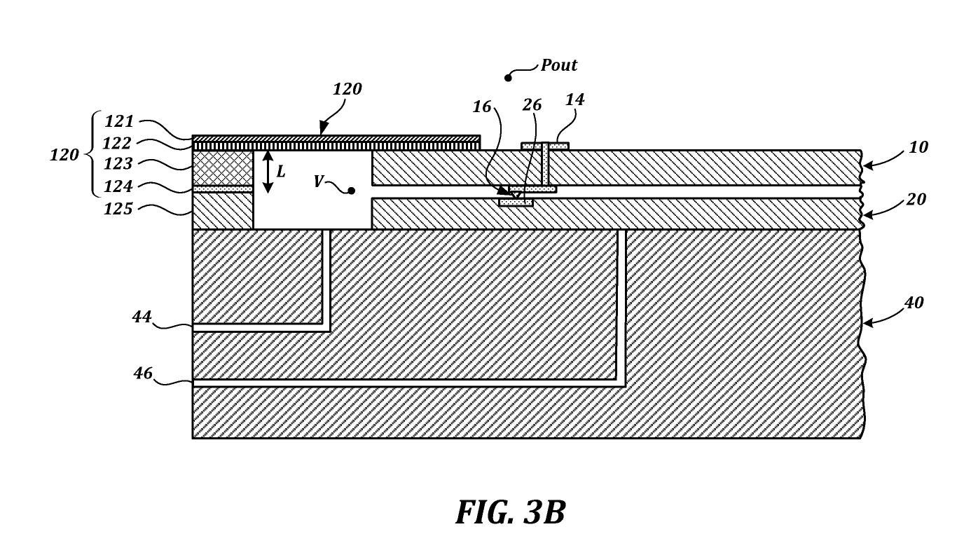

FIGS. 3A and 3B are schematic, cross-sectional views of a wafer translator engaging with a wafer in accordance with an embodiment of the presently disclosed technology. FIG. 3A illustrates the wafer-side contact structure of the wafer translator 10 facing the die contacts of the wafer 20. In some embodiments, a gasket 120 can at least partially seal the space between the wafer translator 10 and the wafer 20. The wafer 20 can be held against the chuck 40 by applying the vacuum through the evacuation path 46, by mechanical clamping, or by other mechanisms. The gasket 120 may include a first top layer 121 and a second top layer 122 that are disposed peripherally about the perimeter of the wafer translator 10. In some embodiments, the first top layer 121 may include polyester or other polymer, and the second top layer 122 may include a material that is adhesive or tacky (e.g., a silicone adhesive) to promote a releasable adhesion of the gasket 120 to the wafer translator 10. The first top layer 121 and/or the second top layer 122 may include a flat area (i.e., a non-circular edge) to facilitate keying and removal of the gasket 120 from the wafer translator 10, for example, after the wafer 20 has been tested. In some embodiments, the gasket 120 may have just one top layer or more than two top layers. For example, the first top layer 121 may include a tacky or adhesive surface facing the wafer therefore at least partially combining the functionality of the first and second top layers.

The illustrated gasket 120 includes an insert 123 and a bottom layer 124. In some embodiments, the insert 123 includes an elastomer (e.g., rubber, silicon rubber, etc.), and the bottom layer 124 includes a material that is adhesive or tacky (e.g., a releasably adhesive material). In some embodiments, a bottom surface of the insert 123 may be adhesive or tacky, therefore combining the functions of the insert 123 and the bottom layer 124. In the illustrated embodiment, the bottom layer 124 of the gasket 120 faces a chuck stand 125. The height of the insert 123, the bottom layer 124, and the chuck stand 125 can be selected to improve contact between the wafer-side contact structures 16 and the corresponding die contacts 26, as explained below in connection with FIG. 3B.

FIG. 3B illustrates the wafer-side contact structure 16 of the wafer translator 10 contacting the die contacts 26 of the wafer 20 in the direction L. In some embodiments, the bottom layer 124 contacts the chuck stand 125 to seal the space between the wafer translator 10 and the wafer 20. The vacuum V (e.g., provided through the evacuation path 44) can maintain contact between the wafer-side contact structure 16 and the die contacts 26 because of the pressure differential between the Pout and V. In some embodiments, the wafer 20 is tested after the wafer-side contact structure 16 contacts the die contacts 26. In some embodiments, the bottom layer 124 can have a stronger adhesion at the side facing the insert 123, and a weaker adhesion at the side facing the chuck stand 125 for easier removal of the gasket 120 from the chuck stand 125.

In some embodiments, the vacuum V can still be maintained even when the height of the stack of the gasket 120 and the chuck stand 125 differs from the combined height of the wafer 20 and the wafer translator 10 due to, for example, manufacturing tolerances. For example, the flexibility of the first top layer 121 and the second top layer 122, and/or the compressibility of the insert 123 may overcome height differences caused by the manufacturing tolerances. In some embodiments, the insert 123 can be about 0.5 mm thick. In some embodiments, thickness of the insert 123 may be comparable to thickness of the wafer translator 10.

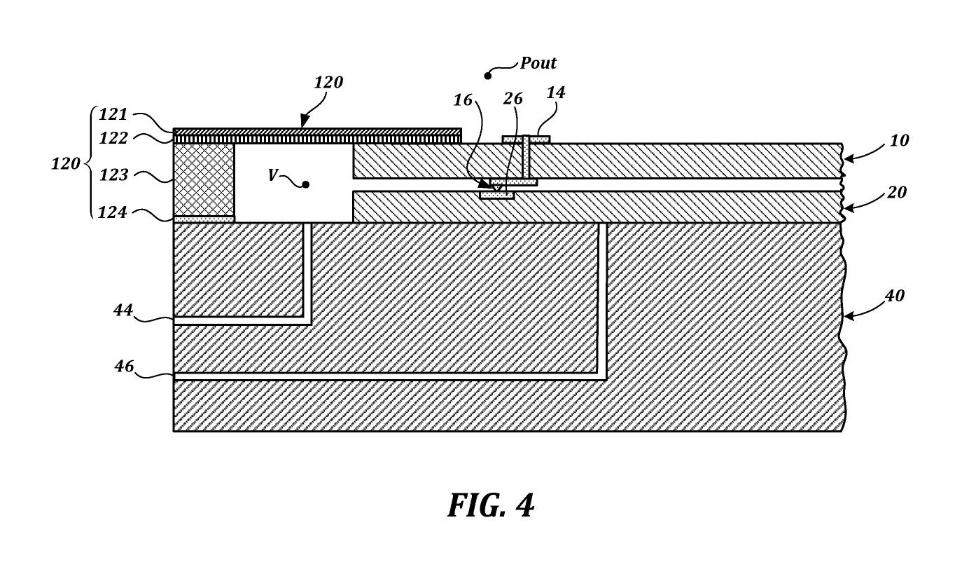

FIG. 4 is a partially schematic, cross-sectional view of a wafer test stack configured in accordance with an embodiment of the presently disclosed technology. In some embodiments, the combined height of the insert 123 and bottom layer 124 is selected such that the bottom layer 124 contacts the wafer chuck 40 without the intermediary chuck stand. The illustrated gasket 120 includes the bottom layer 124 that contacts the wafer chuck 40 to maintain the vacuum V.

From the foregoing, it will be appreciated that specific embodiments of the technology have been described herein for purposes of illustration, but that various modifications may be made without deviating from the disclosure. For example, in some embodiments, the gasket 120 may include additional layers, or may have fewer layers. Furthermore, the second top layer 122 may be more adhesive on the side facing the first top layer 121, and less adhesive on the side facing the wafer translator 120 to facilitate easier removal of the gasket 120 from the wafer translator 10. Moreover, while various advantages and features associated with certain embodiments have been described above in the context of those embodiments, other embodiments may also exhibit such advantages and/or features, and not all embodiments need necessarily exhibit such advantages and/or features to fall within the scope of the technology. Accordingly, the disclosure can encompass other embodiments not expressly shown or described herein.

The embodiments of the invention in which an exclusive property or privilege is claimed are defined as follows:

1. An apparatus for testing semiconductor dies, comprising:
a semiconductor wafer translator having a wafer-side positioned to face toward a device under test, and an inquiry-side facing away from the wafer-side;
a flexible arm peripherally connected to the wafer translator; and
an evacuation opening at least partially disposed within the flexible arm or within the wafer translator

2. The apparatus of claim 1 wherein the evacuation opening is open to a flow of a gas in a first position of the flexible arm, and closed to the flow of the gas in a second position of the flexible arm.

3. The apparatus of claim 2, further comprising a vent seal at least partially disposed inside the evacuation opening, wherein the vent seal closes the evacuation opening in the second position of the flexible arm.

4. The apparatus of claim 2, further comprising a vent seal at least partially disposed over an opening of the evacuation opening, wherein the vent seal closes the evacuation opening in the second position of the flexible arm.

5. The apparatus of claim 1 wherein the flexible arm comprises an elastomer.

6. The apparatus of claim 1 wherein the flexible arm is attached to a chuck attachment.

7. The apparatus of claim 1 wherein the wafer translator is in contact with a semiconductor wafer in the second position of the flexible arm.

8. The apparatus of claim 1, further comprising a semiconductor wafer that carries the semiconductor dies, wherein the wafer translator is in contact with the semiconductor dies of the semiconductor wafer in the second position of the flexible arm.

9. The apparatus of claim 1 wherein the gas is an inert gas.

10. An apparatus for testing semiconductor dies, comprising:
a wafer translator having a wafer-side positioned to face toward a device under test, an inquiry-side facing away from the wafer side, and a side surface connecting the wafer-side and the inquiry-side; and
a gasket in contact with the inquiry-side of the wafer translator, wherein the gasket includes a top layer contacting a periphery of the inquiry-side of the wafer translator, and an insert disposed laterally away from the side surface of the wafer translator and in contact with the top layer.

11. The apparatus of claim 10 wherein the top layer includes a first layer and a second layer, wherein the second layer is in contact with the first layer and the inquiry-side of the wafer translator, and wherein the second layer is adhesive.

12. The apparatus of claim 10 wherein the insert has a first side in contact with the top layer and a second side opposite the first side, and wherein the second side is adhesive.

13. The apparatus of claim 10 wherein the insert has a first side in contact with the top layer and a second side opposite the first side, the apparatus further comprising a bottom layer attached to the insert, wherein the bottom layer is adhesive.

14. The apparatus of claim 10 wherein the insert is permanently attached to the top layer.

15. The apparatus of claim 10 wherein the insert comprises rubber or silicon rubber.

16. The apparatus of claim 10 wherein the wafer-side of the wafer translator carries contact structures having a first scale, and the inquiry-side of the wafer translator carries the contact structures having a second scale, wherein the first scale is smaller than the second scale.

17. The apparatus of claim 10, further comprising a semiconductor wafer that carries the semiconductor dies.

18. A method for testing semiconductor dies, comprising:
generating a vacuum by evacuating a gas from a space between a wafer translator and a semiconductor wafer through an evacuation opening, wherein the wafer translator has a wafer-side facing the semiconductor wafer and an inquiry-side opposite the wafer-side, and wherein the wafer translator is attached to a wafer chuck with a flexible arm peripherally connected to the wafer translator;
in response to generating the vacuum, moving the wafer translator into contact with the semiconductor wafer; and
in response to moving the wafer translator, closing the evacuation opening to the gas.

19. The method of claim 18 wherein a vent seal closes the evacuation path to the gas.

20. The method of claim 18 wherein the evacuation path is at least partially disposed through the flexible arm.

21. The method of claim 18 wherein the gas is evacuated through the wafer chuck.

22. The method of claim 18 wherein the flexible arm is attached to the wafer chuck by a chuck attachment.

23. The method of claim 18 wherein the vacuum is a first vacuum, the method further comprising applying a second vacuum in a space between the semiconductor wafer and the wafer chuck.

24. The method of claim 18, further comprising testing the semiconductor dies.

25. The apparatus of claim 18 wherein the wafer-side of the wafer translator carries contact structures having a first scale, and the inquiry-side of the wafer translator carries the contact structures having a second scale, wherein the first scale is smaller than the second scale.
